(19) United States
(12) Patent Application Publication
(10) Pub. No.: US 2014/0027713 A1
(43) Pub. Date: Jan. 30, 2014

(54) DEVICE INCLUDING QUANTUM DOTS

(71) Applicant: QD Vision, Inc., Lexington, MA (US)

(72) Inventors: Marshall Cox, Brooklyn, NY (US); Craig Breen, Somerville, MA (US); Zhaoqun Zhou, Bedford, MA (US); Jonathan S. Steckel, Carlisle, MA (US)

(73) Assignee: QD Vision, Inc., Lexington, MA (US)

(21) Appl. No.: 14/042,074

(22) Filed: Sep. 30, 2013

Related U.S. Application Data
(63) Continuation of application No. PCT/US2012/023674, filed on Feb. 2, 2012.
(60) Provisional application No. 61/471,141, filed on Apr. 2, 2011.

(51) Int. Cl. H01L 33/04; H01L 33/00

(52) U.S. Cl. CPC H01L 33/04; H01L 33/005
USPC 257/13; 438/47

(57) ABSTRACT

A method for making a device, the method comprising: depositing a layer comprising quantum dots over a first electrode, the quantum dots including ligands attached to the outer surfaces thereof; treating the surface of the deposited layer comprising quantum dots to remove the exposed ligands; and forming a device layer thereover. Also disclosed is a device made in accordance with the disclosed method. Another aspect of the invention relates to a device comprising a first electrode and a second electrode, and a layer comprising quantum dots between the two electrodes, the layer comprising quantum dots deposited from a dispersion that have been treated to remove exposed ligands after formation of the layer in the device. Another aspect of the invention relates to a device comprising a first electrode and a second electrode, a layer comprising a first inorganic semiconductor material disposed between the first and second electrodes, and a plurality of quantum dots disposed between the first and second electrodes, the outer surface of the quantum dots comprising a second inorganic semiconductor material, wherein the composition of the first inorganic semiconductor material and the second inorganic semiconductor material is the same (without regard to any ligands on the outer surface of the quantum dot).

This application is a continuation of commonly owned International Application No. PCT/US2012/023674 filed 2 Feb. 2012, which published in the English language as PCT Publication No. WO 2012/138410 on 11 Oct. 2012, which International Application claims priority to U.S. Application No. 61/471,141 filed 2 Apr. 2011. Each of the foregoing is hereby incorporated herein by reference in its entirety.

### FEDERALLY SPONSORED RESEARCH OR DEVELOPMENT

This invention was made with Government support under Advanced Technology Program Award No. 70NANB7H7056 awarded by NIST. The United States has certain rights in the invention.

### TECHNICAL FIELD OF THE INVENTION

The present invention relates to the technical field of devices including quantum dots.

### SUMMARY OF THE INVENTION

In accordance with one aspect of the present invention there is provided a method for making a device, the method comprising:

depositing a layer comprising quantum dots over a first electrode, the quantum dots including ligands attached to the outer surfaces thereof;

treating the surface of the deposited layer comprising quantum dots to remove the exposed ligands; and

forming a device layer thereover.

Preferably, the exposed ligands are removed without treatment by heat or vacuum.

Examples of preferred treatment techniques for removing exposed ligands include, but are not limited to, oxygen plasma and UV-ozone.

The method may further comprise forming one or more additional predetermined device layers over the first electrode prior to depositing the layer comprising quantum dots.

The device layer can comprise a second electrode.

The method may further optionally further comprise forming one or more additional predetermined device layers, including an electrode, after formation of the device layer.

The method may optionally further comprise a step of packaging the device.

A layer may comprise one or more layers.

In accordance with another aspect of the present invention, there is provided a device prepared in accordance with the method taught herein.

In accordance with another aspect of the present invention, there is provided a device comprising a first electrode and a second electrode, and a layer comprising quantum dots between the two electrodes, the layer comprising quantum dots deposited from a dispersion, the layer having been treated to remove exposed ligands after formation of the layer in the device.

The device may further comprise one or more additional predetermined device layers between the first electrode and the layer comprising quantum dots.

The device may further optionally further comprise one or more additional predetermined device layers between the layer comprising quantum dots and the second electrode.

The device may optionally further comprise packaging.

A layer may comprise one or more layers.

In accordance with an other aspect of the present invention, there is provided a device comprising a first electrode and a second electrode, a layer comprising a first inorganic semiconductor material disposed between the first and second electrodes, and a plurality of quantum dots disposed between the first and second electrodes, the outer surface of the quantum dots comprising a second inorganic semiconductor material, wherein the composition of the first inorganic semiconductor material and the second inorganic semiconductor material is the same (without regard to any ligands on the outer surface of the quantum dot).

The quantum dots can be distributed in the first inorganic semiconductor materials.

The quantum dots can be included in a separate layer disposed between the two electrodes.

Alternatively the first layer can comprise two layers, and the quantum dots can be disposed as a separate layer between the two layers of the first inorganic semiconductor material.

In embodiments including a separate layer comprising quantum dots, the surface of the deposited layer comprising quantum dots is treated to remove the exposed ligands before another device layer is formed thereof.

Preferably, the exposed ligands are removed without treatment by heat or vacuum.

Examples of preferred treatment techniques for removing exposed ligands include, but are not limited to, oxygen plasma and UV-ozone.

If a quantum dot has non-uniform composition (e.g., graded composition, core/shell structure, etc.), the second inorganic semiconductor material is determined by the composition at the outer surface of the quantum dot (without regard to the ligands).

Examples of inorganic semiconductor materials from which the first and second inorganic semiconductor materials are comprised include, but are not limited to, Group II-VI compound semiconductor nanocrystals, such as, but not limited to, CdO, CdS, CdSe, ZnS, ZnSe, ZnTe, HgS, HgSe, HgTe, and other binary, ternary, and quaternary II-VI compositions; Group III-V compound semiconductor nanocrystals, such as, but not limited to, GaP, GaAs, InP and InAs; PbS; PbSe; PbTe, and other binary, ternary, and quaternary III-V compositions. Other non-limiting examples of inorganic semiconductor materials include Group II-V compounds, Group III-VI compounds, Group IV-VI compounds, Group compounds, Group II-IV-VI compounds, Group II-IV-V compounds, Group IV elements, an alloy including any of the foregoing, and/or a mixture including any of the foregoing. metal chalcogenides (e.g., metal oxides, metal sulfides, etc.).

Preferably quantum dots comprise inorganic semiconductor nanocrystals. Such inorganic semiconductor nanocrystals typically comprise a core/shell structure. In certain preferred embodiments, quantum dots comprise colloidally grown inorganic semiconductor nanocrystals.

Quantum dots can include ligands attached to an outer surface thereof that are derived from the growth process and/or ligands that are thereafter exchanged or altered. In certain embodiments, two or more chemically distinct ligands can be attached to an outer surface of at least a portion of the quantum dots.

Quantum dots that can be included in a device or method taught herein can include two or more different types of quantum dots, wherein each type can be selected to emit light having a predetermined wavelength. In certain embodiments, quantum dot types can be different based on, for example, factors such composition, structure and/or size of the quantum dot.

Quantum dots can be selected to emit at any predetermined wavelength across the electromagnetic spectrum.

An emissive layer can include different types of quantum dots that have emissions at different wavelengths.

In certain embodiments, quantum dots can be capable of emitting visible light.

In certain embodiments, quantum dots can be capable of emitting infrared light.

Other aspects and embodiments of the invention relate to materials and methods that are useful in making the above described devices.

The foregoing, and other aspects described herein, all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

It is to be understood that both the foregoing general description and the following detailed description are exemplary and explanatory only and are not restrictive of the invention as claimed. Other embodiments will be apparent to those skilled in the art from consideration of the description and drawings, from the claims, and from practice of the invention disclosed herein.

### BRIEF DESCRIPTION OF THE DRAWINGS

In the drawings:

FIG. 1 is schematic drawing depicting an example of an embodiment of a light-emitting device structure in accordance with the invention.

The attached FIGURE is a simplified representation presented for purposes of illustration only; actual structures may differ in numerous respects, including, e.g., relative scale, etc.

For a better understanding to the present invention, together with other advantages and capabilities thereof, reference is made to the following disclosure and appended claims in connection with the above-described drawings.

### DETAILED DESCRIPTION OF THE INVENTION

Various aspects and embodiments of the present inventions will be further described in the following detailed description.

In accordance with one aspect of the present invention there is provided a method for making a device, the method comprising:

depositing a layer comprising quantum dots over a first electrode, the quantum dots including ligands attached to the outer surfaces thereof;

treating the surface of the deposited layer comprising quantum dots to remove the exposed ligands; and

forming a device layer thereover.

Preferably, the exposed ligands are removed without treatment by heat or vacuum.

Examples of preferred treatment techniques for removing exposed ligands include, but are not limited to, oxygen plasma and UV-ozone.

The method may further comprise forming one or more additional predetermined device layers over the first electrode prior to depositing the layer comprising quantum dots.

The device layer can comprise a second electrode.

The method may further optionally further comprise forming one or more additional predetermined device layers, including an electrode, after formation of the device layer.

The method may optionally further comprise a step of packaging the device.

A layer may comprise one or more layers.

In accordance with another aspect of the present invention, there is provided a device prepared in accordance with the method taught herein.

In accordance with another aspect of the present invention, there is provided a device comprising a first electrode and a second electrode, and a layer comprising quantum dots between the two electrodes, the layer comprising quantum dots deposited from a dispersion that have been treated to remove exposed ligands after formation of the layer in the device.

The device may further comprise one or more additional predetermined device layers between the first electrode and the layer comprising quantum dots.

The device may further optionally further comprise one or more additional predetermined device layers between the layer comprising quantum dots and the second electrode.

The device may optionally further comprise packaging.

A layer may comprise one or more layers.

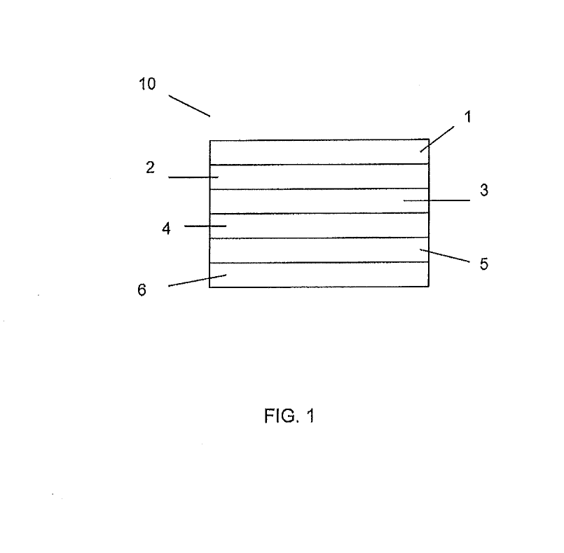

FIG. 1 provides a schematic representation of an example of the architecture of a light-emitting device according to one embodiment of the present invention. Referring to FIG. 1, the light-emitting device 10 includes (from top to bottom) a second electrode (e.g., an anode) 1, a second layer comprising a material capable of transporting charge (e.g., a material capable of transporting holes, which is also referred to herein as a “hole transport material”) 2, an emissive layer including quantum dots 3, a first layer comprising a material capable of transporting charge (e.g., a material capable of transporting electrons, a material capable of transporting and injecting electrons, such materials also being referred to herein as an “electron transport material”) 4, a first electrode (e.g., a cathode) 5, and a substrate 6.

In certain preferred embodiments, the electron transport material comprises an inorganic material.

In certain embodiments, the anode is proximate to and injects holes into the hole transport material while the cathode is proximate to and injects electrons into the electron transport material. The injected holes and injected electrons combine to form an exciton on the quantum dot and emit light. In certain embodiments, a hole injection layer is further included between the anode and the hole transport layer.

In certain embodiments, the device can have an inverted structure.

In certain preferred embodiments, an electron transport material is also capable of injecting electrons.

The substrate 6 can be opaque or transparent. A transparent substrate can be used, for example, in the manufacture of a transparent light emitting device. See, for example, Bulovic, V. et al., Nature 1996, 380, 29; and Gu, G. et al., Appl. Phys. Lett. 1996, 68, 2606-2608, each of which is incorporated by reference in its entirety. The substrate can be rigid or flexible. The substrate can be plastic, metal, semiconductor wafer, or glass. The substrate can be a substrate commonly used in the art. Preferably the substrate has a smooth surface. A substrate surface free of defects is particularly desirable.

The cathode 5 can be formed on the substrate 6. A cathode can comprise, for example, ITO, aluminum, silver, gold, etc. The cathode preferably comprises a material with a work function chosen with regard to the quantum dots included in the device. For example, a cathode comprising indium tin oxide (ITO) can be preferred for use with an emissive material including quantum dots comprising a CdSe core/CdZnSe shell.

Substrates including patterned ITO are commercially available and can be used in making a device according to the present invention.

The layer comprising a material capable of transporting electrons 4 preferably comprises an inorganic material.

Examples of inorganic semiconductor materials include a metal chalcogenide, a metal pnictide, or elemental semiconductor, such as a metal oxide, a metal sulfide, a metal selenide, a metal telluride, a metal nitride, a metal phosphide, a metal arsenide, or metal arsenide. For example, an inorganic semiconductor material can include, without limitation, zinc oxide, a titanium oxide, a niobium oxide, an indium tin oxide, copper oxide, nickel oxide, vanadium oxide, chromium oxide, indium oxide, tin oxide, gallium oxide, manganese oxide, iron oxide, cobalt oxide, aluminum oxide, thallium oxide, silicon oxide, germanium oxide, lead oxide, zirconium oxide, molybdenum oxide, hafnium oxide, tantalum oxide, tungsten oxide, cadmium oxide, iridium oxide, rhodium oxide, ruthenium oxide, osmium oxide, zinc sulfide, zinc selenide, zinc telluride, cadmium sulfide, cadmium selenide, cadmium telluride, mercury sulfide, mercury selenide, mercury telluride, silicon carbide, diamond (carbon), silicon, germanium, aluminum nitride, aluminum phosphide, aluminum arsenide, aluminum antimonide, gallium nitride, gallium phosphide, gallium arsenide, gallium antimonide, indium nitride, indium phosphide, indium arsenide, indium antimonide, thallium nitride, thallium phosphide, thallium arsenide, thallium antimonide, lead sulfide, lead selenide, lead telluride, iron sulfide, indium selenide, indium sulfide, indium telluride, gallium sulfide, gallium selenide, gallium telluride, tin selenide, tin telluride, tin sulfide, magnesium sulfide, magnesium selenide, magnesium telluride, barium titanate, barium zirconate, zirconium silicate, yttria, silicon nitride, and a mixture of two or more thereof.

Preferably the material capable of transporting electrons also is capable of injecting electrons. In certain embodiments, the inorganic material included in the layer capable or transporting and injection electrons comprises an inorganic semiconductor material. A preferred material capable of transporting and injecting electrons comprises zinc oxide.

In certain embodiments, the inorganic semiconductor material can include a dopant.

In certain preferred embodiments, an electron transport material can include an n-type dopant.

An example of a preferred inorganic semiconductor material for inclusion in an electron transport material of a device in accordance with the invention is zinc oxide. In certain embodiments, zinc oxide can be mixed or blended with one or more other inorganic materials, e.g., inorganic semiconductor materials, such as titanium oxide.

As mentioned above, in certain preferred embodiments, a layer comprising a material capable of transporting and injecting electrons can comprise zinc oxide. Such zinc oxide can be prepared, for example, by a sol-gel process. In certain embodiments, the zinc oxide can be chemically modified. Examples of chemical modification include treatment with hydrogen peroxide.

In other preferred embodiments, a layer comprising a material capable of transporting and injecting electrons can comprise a mixture including zinc oxide and titanium oxide.

The electron transport material is preferably included in the device as a layer. In certain embodiments, the layer has a thickness in a range from about 10 nm to 500 nm.

Electron transport materials comprising an inorganic semiconductor material can be deposited at a low temperature, for example, by a known method, such as a vacuum vapor deposition method, an ion-plating method, sputtering, inkjet printing, sol-gel, etc. For example, sputtering is typically performed by applying a high voltage across a low-pressure gas (for example, argon) to create a plasma of electrons and gas ions in a high-energy state. Energized plasma ions strike a target of the desired coating material, causing atoms from that target to be ejected with enough energy to travel to, and bond with, the substrate.

Additional information concerning inorganic materials that may be useful for inclusion in an electron transport layer is disclosed in International Application No. PCT/US2006/005184, filed 15 Feb. 2006, for “Light Emitting Device Including Semiconductor Nanocrystals, which published as WO 2006/088877 on 26 Aug. 2006, and International Application No. PCT/US2009/002123, filed 3 Apr. 2009, by QD Vision, Inc., et al, entitled “Light-Emitting Device Including Quantum Dots”, which published as WO2009/123763 on 8 Oct. 2009, the disclosures of each of which are hereby incorporated herein by reference in their entireties.

In certain embodiments, a material capable of transporting electrons can comprise an organic material. Information related to fabrication of organic charge transport layers that may be helpful are disclosed in U.S. patent application Ser. Nos. 11/253,612 for “Method And System For Transferring A Patterned Material”, filed 21 Oct. 2005 (U.S. Published Application No. 2006/0196375A1, and 11/253,595 for “Light Emitting Device Including Semiconductor Nanocrystals”, filed 21 Oct. 2005 (U.S. Published Application No. 2008/0001167A1), and International Application No. PCT/US2009/002123, filed 3 Apr. 2009, by QD Vision, Inc., et al, entitled “Light-Emitting Device Including Quantum Dots”, which published as WO2009/123763 on 8 Oct. 2009, the foregoing patent applications are hereby incorporated herein by reference in its entirety.

The emissive layer 3 includes quantum dots.

A quantum dot is a nanometer sized particle that can have optical properties arising from quantum confinement. The particular composition(s), structure, and/or size of a quantum dot can be selected to achieve the desired wavelength of light to be emitted from the quantum dot upon stimulation with a particular excitation source. In essence, quantum dots may be tuned to emit light across the visible spectrum by changing their size. See C. B. Murray, C. R. Kagan, and M. G. Bawendi, Annual Review of Material Sci., 2000, 30: 545-610 hereby incorporated by reference in its entirety.

A quantum dot can have an average particle size in a range from about 1 to about 1000 nanometers (nm), and preferably in a range from about 1 to about 100 nm. In certain embodiments, quantum dots have an average particle size in a range from about 1 to about 20 nm (e.g., such as about 5, 6, 7, 8, 9, 10, 11, 12, 13, 14, 15, 16, 17, 18, 19, or 20 nm). In certain embodiments, quantum dots have an average particle size in a range from about 1 to about 10 nm. Quantum dots can have an average diameter less than about 150 Angstroms (Å). In certain embodiments, quantum dots having an average diameter in a range from about 12 to about 150 Å can be particularly desirable. However, depending upon the composition, structure, and desired emission wavelength of the quantum dot, the average diameter may be outside of these ranges.

For convenience, the size of quantum dots can be described in terms of a “diameter”. In the case of spherically shaped quantum dots, diameter is used as is commonly understood. For non-spherical quantum dots, the term diameter can typically refer to a radius of revolution (e.g., a smallest radius of revolution) in which the entire non-spherical quantum dot would fit.

Preferably, a quantum dot comprises a semiconductor nanocrystal. In certain embodiments, a semiconductor nanocrystal has an average particle size in a range from about 1 to about 20 nm, and preferably from about 1 to about 10 nm. However, depending upon the composition, structure, and desired emission wavelength of the quantum dot, the average diameter may be outside of these ranges.

A quantum dot can comprise one or more semiconductor materials.

In certain preferred embodiments, the quantum dots comprise crystalline inorganic semiconductor material (also referred to as semiconductor nanocrystals). Examples of preferred inorganic semiconductor materials include, but are not limited to, Group II-VI compound semiconductor nanocrystals, such as CdS, CdSe, ZnS, ZnSe, ZnTe, HgS, HgSe, HgTe, and other binary, ternary, and quaternary II-VI compositions; Group III-V compound semiconductor nanocrystals, such as GaP, GaAs, InP and InAs; PbS; PbSe; PbTe, and other binary, ternary, and quaternary III-V compositions. Other non-limiting examples of inorganic semiconductor materials include Group II-V compounds, Group III-VI compounds, Group IV-VI compounds, Group compounds, Group II-IV-VI compounds, Group II-IV-V compounds, Group IV elements, an alloy including any of the foregoing, and/or a mixture including any of the foregoing.

A quantum dot can comprise a core comprising one or more semiconductor materials and a shell comprising one or more semiconductor materials, wherein the shell is disposed over at least a portion, and preferably all, of the outer surface of the core. A quantum dot including a core and shell is also referred to as a “core/shell” structure.

In a core/shell quantum dot, the shell or overcoating may comprise one or more layers. The overcoating can comprise at least one semiconductor material which is the same as or different from the composition of the core. Preferably, the overcoating has a thickness from about one to about ten monolayers. An overcoating can also have a thickness greater than ten monolayers. In certain embodiments, more than one overcoating can be included on a core.

In certain embodiments, the shell can be chosen so as to have an atomic spacing close to that of the “core” substrate. In certain other embodiments, the shell and core materials can have the same crystal structure.

Preferred quantum dots for inclusion in an emissive material of a light-emitting device include core-shell structured nanocrystals. Examples include, for example, CdSe/ZnS, CdS/ZnSe, InP/ZnS, etc., wherein the core is composed of a semiconductor nanocrystal comprising a first inorganic semiconductor material (e.g. CdSe, CdS, etc.) and the shell is composed of a second crystalline inorganic semiconductor material (e.g., ZnS, ZnSe, etc.).

Quantum dots can also have various shapes, including, but not limited to, sphere, rod, disk, other shapes, and mixtures of various shaped particles.

An emissive material can comprise one or more different quantum dots. The differences can be based, for example, on different composition, different size, different structure, or other distinguishing characteristic or property.

The color of the light output of a light-emitting device can be controlled by the selection of the composition, structure, and size of the quantum dots included in a light-emitting device as the emissive material.

The emissive material is preferably included in the device as a layer. In certain embodiments, the emissive layer can comprise one or more layers of the same or different emissive material(s). In certain embodiments, the emissive layer can have a thickness in a range from about 1 nm to about 20 nm. In certain embodiments, the emissive layer can have a thickness in a range from about 1 nm to about 10 nm. In certain embodiments, the emissive layer can have a thickness in a range from about 3 nm to about 6 about nm. In certain embodiments, the emissive layer can have a thickness of about 4 nm. A thickness of 4 nm can be preferred in a device including an electron transport material including a metal oxide. Other thicknesses outside the above examples may also be determined to be useful or desirable.

The quantum dots are typically colloidally grown and include one or more ligands attached to the surface thereof. In certain embodiments, a ligand can include an alkyl (e.g., C₁-C₂₀) species. In certain embodiments, an alkyl species can be straight-chain, branched, or cyclic. In certain embodiments, an alkyl species can be substituted or unsubstituted. In certain embodiments, an alkyl species can include a hetero-atom in the chain or cyclic species. In certain embodiments, a ligand can include an aromatic species. In certain embodiments, an aromatic species can be substituted or unsubstituted. In certain embodiments, an aromatic species can include a hetero-atom. Additional information concerning ligands is provided.

By controlling the structure, shape and size of quantum dots during preparation, energy levels over a very broad range of wavelengths can be obtained while the properties of the bulky materials are varied. Quantum dots (including but not limited to semiconductor nanocrystals) can be prepared by known techniques. Preferably they are prepared by a wet chemistry technique wherein a precursor material is added to a coordinating or non-coordinating solvent (typically organic) and nanocrystals are grown so as to have an intended size. According to the wet chemistry technique, when a coordinating solvent is used, as the quantum dots are grown, the organic solvent is naturally coordinated to the surface of the quantum dots, acting as a dispersant. Accordingly, the organic solvent allows the quantum dots to grow to the nanometer-scale level. The wet chemistry technique has an advantage in that quantum dots of a variety of sizes can be uniformly prepared by appropriately controlling the concentration of precursors used, the kind of organic solvents, and preparation temperature and time, etc.

A coordinating solvent can help control the growth of quantum dots. The coordinating solvent is a compound having a donor lone pair that, for example, has a lone electron pair available to coordinate to a surface of the growing quantum dots. Solvent coordination can stabilize the growing quantum dot. Examples of coordinating solvents include alkyl phosphines, alkyl phosphine oxides, alkyl phosphonic acids, or alkyl phosphinic acids, however, other coordinating solvents, such as pyridines, furans, and amines may also be suitable for quantum dot production. Additional examples of suitable coordinating solvents include pyridine, tri-n-octyl phosphine (TOP), tri-n-octyl phosphine oxide (TOPO) and trishydroxylpropylphosphine (tHPP), tributylphosphine, tri(dodecyl)phosphine, dibutyl-phosphite, tributyl phosphite, trioctadecyl phosphite, trilauryl phosphite, tris(tridecyl)phosphite, triisodecyl phosphite, bis(2-ethylhexyl)phosphate, tris(tridecyl)phosphate, hexadecylamine, oleylamine, octadecylamine, bis(2-ethylhexyl)amine, octylamine, dioctylamine, trioctylamine, dodecylamine/laurylamine, didodecylamine tridodecylamine, hexadecylamine, dioctadecylamine, trioctadecylamine, phenylphosphonic acid, hexylphosphonic acid, tetradecylphosphonic acid, octylphosphonic acid, octadecylphosphonic acid, propylenediphosphonic acid, phenylphosphonic acid, aminohexylphosphonic acid, dioctyl ether, diphenyl ether, methyl myristate, octyl octanoate, and hexyl octanoate. In certain embodiments, technical grade TOPO can be used.

Quantum dots can alternatively be prepared with use of non-coordinating solvent(s).

Size distribution during the growth stage of the reaction can be estimated by monitoring the absorption or emission line widths of the particles. Modification of the reaction temperature in response to changes in the absorption spectrum of the particles allows the maintenance of a sharp particle size distribution during growth. Reactants can be added to the nucleation solution during crystal growth to grow larger crystals. For example, for CdSe and CdTe, by stopping growth at a particular semiconductor nanocrystal average diameter and choosing the proper composition of the semiconducting material, the emission spectra of the semiconductor nanocrystals can be tuned continuously over the wavelength range of 300 nm to 5 microns, or from 400 nm to 800 nm.

The particle size distribution of quantum dots can be further refined by size selective precipitation with a poor solvent for the quantum dots, such as methanol/butanol as described in U.S. Pat. No. 6,322,901. For example, semiconductor nanocrystals can be dispersed in a solution of 10% butanol in hexane. Methanol can be added dropwise to this stirring solution until opalescence persists. Separation of supernatant and flocculate by centrifugation produces a precipitate enriched with the largest crystallites in the sample. This procedure can be repeated until no further sharpening of the optical absorption spectrum is noted. Size-selective precipitation can be carried out in a variety of solvent/nonsolvent pairs, including pyridine/hexane and chloroform/methanol. The size-selected quantum dot population preferably has no more than a 15% rms deviation from mean diameter, more preferably 10% rms deviation or less, and most preferably 5% rms deviation or less.

In certain embodiment, the ligands can be derived from the coordinating solvent used during the growth process.

In certain embodiments, the surface can be modified by repeated exposure to an excess of a competing coordinating group to form an overlayer.

For example, a dispersion of the capped semiconductor nanocrystal can be treated with a coordinating organic compound, such as pyridine, to produce crystallites which disperse readily in pyridine, methanol, and aromatics but no longer disperse in aliphatic solvents. Such a surface exchange process can be carried out with any compound capable of coordinating to or bonding with the outer surface of the semiconductor nanocrystal, including, for example, phosphines, thiols, amines and phosphates. The semiconductor nanocrystal can be exposed to short chain polymers which exhibit an affinity for the surface and which terminate in a moiety having an affinity for a liquid medium in which the semiconductor nanocrystal is suspended or dispersed. Such affinity improves the stability of the suspension and discourages flocculation of the semiconductor nanocrystal.

A suitable coordinating ligand can be purchased commercially or prepared by ordinary synthetic organic techniques, for example, as described in J. March, Advanced Organic Chemistry.

Other ligands are described in U.S. patent application Ser. No. 10/641,292 for “Stabilized Semiconductor Nanocrystals”, filed 15 Aug. 2003, which issued on 9 Jan. 2007 as U.S. Pat. No. 7,160,613, which is hereby incorporated herein by reference in its entirety.

Other examples of ligands include benzylphosphonic acid, benzylphosphonic acid including at least one substituent group on the ring of the benzyl group, a conjugate base of such acids, and mixtures including one or more of the foregoing. In certain embodiments, a ligand comprises 4-hydroxybenzylphosphonic acid, a conjugate base of the acid, or a mixture of the foregoing. In certain embodiments, a ligand comprises 3,5-di-tert-butyl-4-hydroxybenzylphosphonic acid, a conjugate base of the acid, or a mixture of the foregoing.

Additional examples of ligands that may be useful with the present invention are described in International Application No. PCT/US2008/010651, filed 12 Sep. 2008, of Breen, et al., for “Functionalized Nanoparticles And Method” and International Application No. PCT/US2009/004345, filed 28 Jul. 2009 of Breen et al., for “Nanoparticle Including Multi-Functional Ligand And Method”, each of the foregoing being hereby incorporated herein by reference.

The emission from a quantum dot capable of emitting light (e.g., a semiconductor nanocrystal) can be a narrow Gaussian emission band that can be tuned through the complete wavelength range of the ultraviolet, visible, or infra-red regions of the spectrum by varying the size of the quantum dot, the composition of the quantum dot, or both. For example, a semiconductor nanocrystal comprising CdSe can be tuned in the visible region; a semiconductor nanocrystal comprising InAs can be tuned in the infra-red region. The narrow size distribution of a population of quantum dots capable of emitting light (e.g., semiconductor nanocrystals) can result in emission of light in a narrow spectral range. The population can be monodisperse preferably exhibits less than a 15% rms (root-mean-square) deviation in diameter of such quantum dots, more preferably less than 10%, most preferably less than 5%. Spectral emissions in a narrow range of no greater than about 75 nm, no greater than about 60 nm, no greater than about 40 nm, and no greater than about 30 nm full width at half max (FWHM) for such quantum dots that emit in the visible can be observed. IR-emitting quantum dots can have a FWHM of no greater than 150 nm, or no greater than 100 nm. Expressed in terms of the energy of the emission, the emission can have a FWHM of no greater than 0.05 eV, or no greater than 0.03 eV. The breadth of the emission decreases as the dispersity of the light-emitting quantum dot diameters decreases.

For example, semiconductor nanocrystals can have high emission quantum efficiencies such as greater than 10%, 20%, 30%, 40%, 50%, 60%, 70%, 80%, or 90%.

The narrow FWHM of semiconductor nanocrystals can result in saturated color emission. The broadly tunable, saturated color emission over the entire visible spectrum of a single material system is unmatched by any class of organic chromophores (see, for example, Dabbousi et al., J. Phys. Chem. 101, 9463 (1997), which is incorporated by reference in its entirety). A monodisperse population of semiconductor nanocrystals will emit light spanning a narrow range of wavelengths. A pattern including more than one size of semiconductor nanocrystal can emit light in more than one narrow range of wavelengths. The color of emitted light perceived by a viewer can be controlled by selecting appropriate combinations of semiconductor nanocrystal sizes and materials. The degeneracy of the band edge energy levels of semiconductor nanocrystals facilitates capture and radiative recombination of all possible excitons.

Transmission electron microscopy (TEM) can provide information about the size, shape, and distribution of the semiconductor nanocrystal population. Powder X-ray diffraction (XRD) patterns can provide the most complete information regarding the type and quality of the crystal structure of the semiconductor nanocrystals. Estimates of size are also possible since particle diameter is inversely related, via the X-ray coherence length, to the peak width. For example, the diameter of the semiconductor nanocrystal can be measured directly by transmission electron microscopy or estimated from X-ray diffraction data using, for example, the Scherrer equation. It also can be estimated from the UV/Vis absorption spectrum.

An emissive material is typically deposited by a liquid-based technique including an ink comprising quantum dots dispersed in a liquid. Examples of liquid-based techniques for depositing an emissive material include, e.g., but not limited to, spin-casting, screen-printing, inkjet printing, gravure printing, roll coating, drop-casting, Langmuir-Blodgett techniques, contact printing or other liquid-based techniques known or readily identified by one skilled in the relevant art. (For additional related information, see, for example, U.S. patent application Ser. Nos. 11/253,612 for “Method And System For Transferring A Patterned Material”, filed 21 Oct. 2005, and 11/253,595 for “Light Emitting Device Including Semiconductor Nanocrystals”, filed 21 Oct. 2005, International Application No. PCT/US2007/008873, filed Apr. 9, 2007, of Coe-Sullivan et al., for “Composition Including Material, Methods Of Depositing Material, Articles Including Same And Systems For Depositing Material”, which are hereby incorporated herein by reference.)

In accordance with one aspect of the present invention, after the layer comprising quantum dots is deposited and formed in the device (e.g., after removal of solvent in which the quantum dots are dispersed when deposited), the layer is treated to remove exposed ligands.

Preferably, the ligand are removed by techniques other than treatment by heat or vacuum.

Examples of preferred treatment techniques for removing exposed ligands include, but are not limited to, oxygen plasma and UV-ozone. Such techniques are carried out under conditions effective to remove the exposed ligands as determined by the skill artisan.

After removal of the exposed ligands, a device layer is formed over the treated quantum dot layer.

A hole transport material is preferably included in the device as a layer.

A hole transport layer can have a thickness in a range from about 10 nm to about 500 nm.

Examples of hole transport materials include organic material and inorganic materials. An example of an organic material that can be included in a hole transport layer includes an organic chromophore. The organic chromophore can include a phenyl amine, such as, for example, N,N′-diphenyl-N,N′-bis(3-methylphenyl)-(1,1′-biphenyl)-4,4′-diamine (TPD). Other hole transport layer can include (N,N′-bis(3-methylphenyl)-N,N′-bis(phenyl)-spiro (spiro-TPD), 4-4′-N,N′-dicarbazolyl-biphenyl (CBP), 4,4-.bis[N-(1-naphthyl)-N-phenylamino]biphenyl (NPD), etc., a polyaniline, a polypyrrole, a poly(phenylene vinylene), copper phthalocyanine, an aromatic tertiary amine or polynuclear aromatic tertiary amine, a 4,4′-bis(p-carbazolyl)-1,1′-biphenyl compound, N,N,N′,N′-tetraarylbenzidine, poly(3,4-ethylenedioxythiophene) (PEDOT)/polystyrene para-sulfonate (PSS) derivatives, poly-N-vinylcarbazole derivatives, polyphenylenevinylene derivatives, polyparaphenylene derivatives, polymethacrylate derivatives, poly(9,9-octylfluorene) derivatives, poly(spiro-fluorene) derivatives, N,N′-di(naphthalene-1-yl)-N,N-diphenyl-benzidine (NPB), tris(3-methylphenylphenylamino)-triphenylamine (m-MTDATA), and poly(9,9′-dioctylfluorene-co-N-(4-butylphenyl)diphenylamine (TFB), and spiro-NPB.

In certain preferred embodiments, a hole transport layer comprises an organic small molecule material, a polymer, a spiro-compound (e.g., spiro-NPB), etc.

Organic hole transport materials may be deposited by known methods such as a vacuum vapor deposition method, a sputtering method, a dip-coating method, a spin-coating method, a casting method, a bar-coating method, a roll-coating method, and other film deposition methods. Preferably, organic layers are deposited under ultra-high vacuum (e.g., ≦10⁻⁸ torr), high vacuum (e.g., from about 10⁻⁸ torr to about 10⁻⁵ torr), or low vacuum conditions (e.g., from about 10⁻⁵ torr to about 10⁻³ torr).

Hole transport materials comprising organic materials and other information related to fabrication of organic charge transport layers that may be helpful are disclosed in U.S. patent application Ser. Nos. 11/253,612 for “Method And System For Transferring A Patterned Material”, filed 21 Oct. 2005, and 11/253,595 for “Light Emitting Device Including Semiconductor Nanocrystals”, filed 21 Oct. 2005, each of which is hereby incorporated herein by reference in its entirety.

In certain embodiments of the inventions described herein, a hole transport layer can comprise an inorganic material. Examples of inorganic materials include, for example, inorganic semiconductor materials capable of transporting holes. The inorganic material can be amorphous or polycrystalline. Examples of such inorganic materials and other information related to fabrication of inorganic hole transport materials that may be helpful are disclosed in International Application No. PCT/US2006/005184, filed 15 Feb. 2006, for “Light Emitting Device Including Semiconductor Nanocrystals, which published as WO 2006/088877 on 26 Aug. 2006, the disclosure of which is hereby incorporated herein by reference in its entirety.

Hole transport materials comprising, for example, an inorganic material such as an inorganic semiconductor material, can be deposited at a low temperature, for example, by a known method, such as a vacuum vapor deposition method, an ion-plating method, sputtering, inkjet printing, sol-gel, etc.

Device 10 can further include a hole-injection material. The hole-injection material may comprise a separate hole injection material or may comprise an upper portion of the hole transport layer that has been doped, preferably p-type doped. The hole-injection material can be inorganic or organic. Examples of organic hole injection materials include, but are not limited to, LG-101 (see, for example, paragraph (0024) of EP 1 843 411 A1) and other HIL materials available from LG Chem, LTD. Other organic hole injection materials can be used. Examples of p-type dopants include, but are not limited to, stable, acceptor-type organic molecular material, which can lead to an increased hole conductivity in the doped layer, in comparison with a non-doped layer. In certain embodiments, a dopant comprising an organic molecular material can have a high molecular mass, such as, for example, at least 300 amu. Examples of dopants include, without limitation, F₄-TCNQ, FeCl₃, etc. Examples of doped organic materials for use as a hole injection material include, but are not limited to, an evaporated hole transport material comprising, e.g., 4,4′,4″-tris (diphenyl-amino)triphenylamine (TDATA) that is doped with tetrafluoro-tetracyano-quinodimethane (F₄-TCNQ); p-doped phthalocyanine (e.g., zinc-phthalocyanine (ZnPc) doped with F₄-TCNQ (at, for instance, a molar doping ratio of approximately 1:30); N,N′-diphenyl-N,N′-bis(1-naphthyl)-1,1′biphenyl-4,4″diamine (alpha-NPD) doped with F₄-TCNQ. See J. Blochwitz, et al., “Interface Electronic Structure Of Organic Semiconductors With Controlled Doping Levels”, Organic Electronics 2 (2001) 97-104; R. Schmechel, 48, Internationales Wissenschaftliches Kolloquium, Technische Universtaat Ilmenau, 22-25 Sep. 2003; C. Chan et al., “Contact Potential Difference Measurements Of Doped Organic Molecular Thin Films”, J. Vac. Sci. Technol. A 22(4), July/August 2004. The disclosures of the foregoing papers are hereby incorporated herein by reference in their entireties.

As shown in FIG. 1, anode 1 may comprise an electrically conductive metal or its oxide that can easily inject holes. Examples include, but are not limited to, ITO, aluminum, aluminum-doped zinc oxide (AZO), silver, gold, etc. Other suitable anode materials are known and can be readily ascertained by the skilled artisan. The anode material can be deposited using any suitable technique. In certain embodiments, the anode can be patterned.

In certain embodiments, the electrode (e.g., anode or cathode) materials and other materials are selected based on the light transparency characteristics thereof so that a device can be prepared that emits light from the top surface thereof. A top emitting device can be advantageous for constructing an active matrix device (e.g., a display). In certain embodiments, the electrode (e.g., anode or cathode) materials and other materials are selected based on light transparency characteristics thereof so that a device can be prepared that emits light from the bottom surface thereof.

As mentioned above, the device can further include a substrate 6. Examples of substrate materials include, without limitation, glass, plastic, insulated metal foil.

In certain embodiments, a device can further include a passivation or other protective layer that can be used to protect the device from the environment. For example, a protective glass layer can be included to encapsulate the device. Optionally a desiccant or other moisture absorptive material can be included in the device before it is sealed, e.g., with an epoxy, such as a UV curable epoxy. Other desiccants or moisture absorptive materials can be used.

A layer comprising an inorganic semiconductor material that includes a stratified structure (as described in International Application No. PCT/US2010/051867 of QD Vision, Inc. filed 7 Oct. 2010 entitled: ““Device Including Quantum Dots, which is hereby incorporated herein by reference in its entirety) can serve as a layer capable of transporting electrons, injecting electrons, and/or blocking holes.

A device in accordance with the present invention can further optionally include one or more interfacial layers as also described in above-referenced International Application No. PCT/US2010/051867.

In accordance with an other aspect of the present invention, there is provided a device comprising a first electrode and a second electrode, a layer comprising a first inorganic semiconductor material disposed between the first and second electrodes, and a plurality of quantum dots disposed between the first and second electrodes, the outer surface of the quantum dots comprising a second inorganic semiconductor material, wherein the composition of the first inorganic semiconductor material and the second inorganic semiconductor material is the same (without regard to any ligands on the outer surface of the quantum dot).

The quantum dots can be distributed in the first inorganic semiconductor materials.

Alternatively the first layer can comprise two layers, and the quantum dots can be disposed as a separate layer between the two layers of the first inorganic semiconductor material.

The quantum dots can be included in a separate layer disposed between the two electrodes.

Alternatively the first layer can comprise two layers, and the quantum dots can be disposed as a separate layer between the two layers of the first inorganic semiconductor material.

In embodiments including a separate layer comprising quantum dots, the surface of the deposited layer comprising quantum dots is treated to remove the exposed ligands before another device layer is formed thereof.

Preferably, the exposed ligands are removed without treatment by heat or vacuum.

Examples of preferred treatment techniques for removing exposed ligands include, but are not limited to, oxygen plasma and UV-ozone.

If a quantum dot has non-uniform composition (e.g., graded composition, core/shell structure, etc.), the composition of the second inorganic semiconductor material is determined by the composition at the outer surface of the quantum dot (without regard to the ligands).

Examples of inorganic semiconductor materials from which the first and second inorganic semiconductor materials are comprised include, but are not limited to, Group II-VI compound semiconductor nanocrystals, such as, but not limited to, CdO, CdS, CdSe, ZnS, ZnSe, ZnTe, HgS, HgSe, HgTe, and other binary, ternary, and quaternary II-VI compositions; Group III-V compound semiconductor nanocrystals, such as, but not limited to, GaP, GaAs, InP and InAs; PbS; PbSe; PbTe, and other binary, ternary, and quaternary III-V compositions. Other non-limiting examples of inorganic semiconductor materials include Group II-V compounds, Group III-VI compounds, Group IV-VI compounds, Group compounds, Group II-IV-VI compounds, Group II-IV-V compounds, Group IV elements, an alloy including any of the foregoing, and/or a mixture including any of the foregoing. metal chalcogenides (e.g., metal oxides, metal sulfides, etc.).

Preferably quantum dots comprise inorganic semiconductor nanocrystals. Such inorganic semiconductor nanocrystals typically comprise a core/shell structure. In certain preferred embodiments, quantum dots comprise colloidally grown inorganic semiconductor nanocrystals.

In certain embodiments, the quantum dot can comprise a core/shell structure in which the core comprises cadmium selenide (CdSe) and the shell comprises zinc sulfide (ZnS).

Preferably, quantum dots including a ZnS shell are distributed within a layer or matrix comprising a first inorganic semiconductor material which also comprises zinc sulfide.

The quantum dot shell, ZnS, may interact favorably to being incorporated into the ZnS matrix, and this may result in beneficial device performance.

As discussed above, quantum dots can be deposited in an electroluminescent device by a liquid-based techniques, e.g., via spin-coating or micro-contact printing (other forms of solution deposition applicable). The incorporation of ZnS into this system includes thermal evaporation before and/or after QD deposition, or sol-gel application before, intrinsic to, or after QD deposition. The layer can serve to be a buffer layer to other necessary charge-annealing steps that can be included in device fabrication.

Zinc sulfide is a preferred material for inclusion in the layer comprising a first inorganic semiconductor material as thermal evaporation of ZnS requires only ZnS, which does not dissociate in vacuum at temperatures pertinent to thermal evaporation, and no other treatment is required. ZnS can alternatively be formed by sol-gel processing according to established literature preparations.

Quantum dots can include ligands attached to an outer surface thereof that are derived from the growth process and/or ligands that are thereafter exchanged or altered. In certain embodiments, two or more chemically distinct ligands can be attached to an outer surface of at least a portion of the quantum dots.

Quantum dots that can be included in a device or method taught herein can include two or more different types of quantum dots, wherein each type can be selected to emit light having a predetermined wavelength. In certain embodiments, quantum dot types can be different based on, for example, factors such composition, structure and/or size of the quantum dot.

Quantum dots can be selected to emit at any predetermined wavelength across the electromagnetic spectrum.

An emissive layer can include different types of quantum dots that have emissions at different wavelengths.

In certain embodiments, quantum dots can be capable of emitting visible light.

In certain embodiments, quantum dots can be capable of emitting infrared light.

A light-emitting device in accordance with the invention can be used to make a light-emitting device including red-emitting, green-emitting, and/or blue-emitting quantum dots. Other color light-emitting quantum dots can be included, alone or in combination with one or more other different quantum dots. In certain embodiments, separate layers of one or more different quantum dots may be desirable. In certain embodiments, a layer can include a mixture of two or more different quantum dots.

Light-emitting devices in accordance with various embodiments of the invention may be incorporated into a wide variety of consumer products, including flat panel displays, computer monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, a sign, lamps and various solid state lighting devices.

In certain embodiments, a device taught herein can comprise a photodetector device including a layer comprising quantum dots selected based upon absorption properties. When included in a photodetector, quantum dots are engineered to produce a predetermined electrical response upon absorption of a particular wavelength, typically in the IR or MIR region of the spectrum. Examples of photodetector devices including quantum dots (e.g., semiconductor nanocrystals) are described in “A Quantum Dot Heterojunction Photodetector” by Alexi Cosmos Arango, Submitted to the Department of Electrical Engineering and Computer Science, in partial fulfillment of the requirements for the degree of Masters of Science in Computer Science and Engineering at the Massachusetts Institute of Technology, February 2005, the disclosure of which is hereby incorporated herein by reference in its entirety.

Other materials, techniques, methods, applications, and information that may be useful with the present invention are described in: International Application No. PCT/US2007/013152, filed Jun. 4, 2007, of Coe-Sullivan, et al., for “Light-Emitting Devices And Displays With Improved Performance”; International Application No. PCT/US2010/056397 of Kazlas, et al., filed 11 Nov. 2010, entitled “Device Including Quantum Dots”, and International Application No. PCT/US2008/013504, filed Dec. 8, 2008, entitled “Flexible Devices Including Semiconductor Nanocrystals, Arrays, and Methods”, of Kazlas, et al., which published as WO2009/099425 on Aug. 13, 2009, U.S. patent application Ser. Nos. 11/253,612 for “Method And System For Transferring A Patterned Material”, filed 21 Oct. 2005, and 11/253,595 for “Light Emitting Device Including Semiconductor Nanocrystals”, filed 21 Oct. 2005, International Application No. PCT/US2007/008873, filed Apr. 9, 2007, of Coe-Sullivan et al., for “Composition Including Material, Methods Of Depositing Material, Articles Including Same And Systems For Depositing Material”; International Application No. PCT/US2008/010651, filed 12 Sep. 2008, of Breen, et al., for “Functionalized Nanoparticles And Method” and International Application No. PCT/US2009/004345, filed 28 Jul. 2009 of Breen et al., for “Nanoparticle Including Multi-Functional Ligand And Method”, and International Application No. PCT/US2009/002789 of Coe-Sullivan et al, filed 6 May 2009, entitled: “Solid State Lighting Devices Including Quantum Confined Semiconductor Nanoparticles, An Optical Component For A Solid State Light Device, And Methods each of the foregoing being hereby incorporated herein by reference in its entirety.

As used herein, the singular forms “a”, “an” and “the” include plural unless the context clearly dictates otherwise. Thus, for example, reference to an emissive material includes reference to one or more of such materials.

As used herein, “top” and “bottom” are relative positional terms, based upon a location from a reference point. More particularly, “top” means furthest away from the substrate, while “bottom” means closest to the substrate. For example, for a light-emitting device including two electrodes, the bottom electrode is the electrode closest to the substrate, and is generally the first electrode fabricated; the top electrode is the electrode that is more remote from the substrate, on the top side of the light-emitting material. The bottom electrode has two surfaces, a bottom surface closest to the substrate, and a top surface farther away from the substrate. Where, e.g., a layer is described as disposed or deposited “over” another layer, component, or substrate, there may be other layers, components, etc. between the layer and the other layer, component or substrate unless it is otherwise specified. For example, a cathode may be described as “disposed over” an anode, even though there are various organic and/or inorganic layers in between.

The entire contents of all patent publications and other publications cited in this disclosure are hereby incorporated herein by reference in their entirety. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1-16. (canceled)

17. A device comprising a first electrode and a second electrode, a layer comprising a first inorganic semiconductor material disposed between the first and second electrodes, and a plurality of quantum dots disposed between the first and second electrodes, the outer surface of the quantum dots comprising a second inorganic semiconductor material, wherein the composition of the first inorganic semiconductor material and the second inorganic semiconductor material is the same (without regard to any ligands on the outer surface of the quantum dot).

18. A device in accordance with claim 17 wherein the quantum dots are distributed in the first inorganic semiconductor material.

19. A device in accordance with claim 17 wherein the quantum dots are included in a separate layer disposed between the two electrodes.

20. A device in accordance with claim 17 wherein the first layer comprises two layers, and the quantum dots can be disposed as a separate layer between the two layers of the first inorganic semiconductor material.

21. A device in accordance with claim 19 wherein the quantum dots are deposited from a liquid dispersion in which they are dispersed, and the surface of the resulting quantum dot layer is treated to remove the exposed ligands before another device layer is formed thereof.

22. A device in accordance with claim 20 wherein the quantum dots are deposited from a liquid dispersion in which they are dispersed, and the surface of the resulting quantum dot layer is treated to remove the exposed ligands before another device layer is formed thereof.

23. A device in accordance with claim 21 wherein the exposed ligands are removed without treatment by heat or vacuum.

24. A device in accordance with claim 22 wherein the exposed ligands are removed without treatment by heat or vacuum.

25. A device in accordance with claim 21 wherein the exposed ligands are removed by oxygen plasma treatment.

26. A device in accordance with claim 22 wherein the exposed ligands are removed by UV-ozone treatment.

27. A device in accordance with claim 21 wherein the exposed ligands are removed by oxygen plasma treatment.

28. A device in accordance with claim 22 wherein the exposed ligands are removed by UV-ozone treatment.

29. A device in accordance with claim 17 wherein the first inorganic semiconductor material and the second inorganic semiconductor material comprise a II-VI inorganic semiconductor material.

30. A device in accordance with claim 17 wherein the first inorganic semiconductor material and the second inorganic semiconductor material comprise a III-V inorganic semiconductor material.

31. A device in accordance with claim 17 wherein the device is a light-emitting device and the quantum dots are electroluminescent.

32-34. (canceled)

35. A method for making a light-emitting device, the method comprising:
forming a first layer comprising an inorganic charge transport layer over a first electrode,
depositing an emissive layer comprising quantum dots over the first layer, the quantum dots including ligands attached to the outer surfaces thereof;
treating the surface of the deposited layer comprising quantum dots to remove the exposed ligands; and
forming a second device layer thereover, wherein forming the second device layer comprises evaporation of a layer comprising an inorganic semiconductor material.

36. (canceled)

37. A method in accordance with claim 35 wherein forming the second device layer comprises evaporation of a layer comprising a II-VI inorganic semiconductor material.

38. A method in accordance with claim 35 wherein forming the second device layer comprises evaporation of a layer comprising a III-V inorganic semiconductor material.

39. A method in accordance with claim 35 wherein forming the second device layer comprises evaporation of a layer comprising an organic semiconductor material.

40. A method in accordance with claim 37 wherein the II-VI inorganic semiconductor material comprises an oxide compound.

41. A method in accordance with claim 37 wherein the II-VI inorganic semiconductor material comprises sulfide compound.

42. A method in accordance with claim 37 wherein the II-VI inorganic semiconductor material comprises selenide compound.

43. (canceled)
